(19) United States
(12) Patent Application Publication
(10) Pub. No.: US 2010/0148308 A1
(43) Pub. Date: Jun. 17, 2010

(54) Dopant Profile Control for Ultrashallow Arsenic Dopant Profiles

(75) Inventors: Alfred HAEUSLER, Freising (DE); Wolfgang SCHWARTZ, Reichertshausen (DE)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/637,857

(22) Filed: Dec. 15, 2009

(30) Foreign Application Priority Data
Dec. 17, 2008 (DE) 10 2008 062 693.7

(51) Int. Cl. H01L 29/73; H01L 21/265; H01L 29/12

(52) U.S. Cl. 257/565; 438/530; 257/607; 257/E21.334; 257/E29.068; 257/E29.174

(57) ABSTRACT

A method of manufacturing a semiconductor device comprises growing or depositing an implantation oxide layer, implanting a dopant, activating the dopant, and removing the implantation oxide layer after the step of activating the dopant.

### FIELD OF THE INVENTION

The present invention generally relates to a method of manufacturing a semiconductor device. More particularly, the present invention relates to an improved method for fabricating an NPN transistor in BICMOS technology (bipolar and CMOS transistors integrated in the same device).

### BACKGROUND

In today's advanced BICMOS technologies, where bipolar and CMOS transistors can be integrated in the same semiconductor device, the requirements for control of the dopants used in such semiconductor devices are becoming ever more stringent. Especially heavy ions are used as the dopant to generate the required ultra-shallow implanted and diffused dopant profile.

FIG. 1 shows a simplified schematic of a part of a semiconductor device 1 manufactured according to a known method. A layer 11 forms the active region and can be a silicon layer, for example. An oxide layer 12 is provided on top of the layer 11, with a nitride layer 13, for example a silicon nitride layer (Si₃Ni₄) being provided on top of the oxide layer 12. Etching of the nitride layer 13 and a partial etching of the oxide layer 12 is performed. A dopant profile 15 is established by implanting dopant atoms or ions, for example arsenic, through the residual oxide layer into the layer 11 forming the active region of the device 1. The residual implantation oxide layer is then removed so that it forms the profile 15 for the base region. A polysilicon layer 14 is then deposited on top of the silicon nitride layer 13 and into the open window which forms the emitter. Finally, the dopant is activated by heating the electronic device 1.

Because of the shallow profile to be established, the implant doping profile can vary a great deal with implantation condition variations such as implant angle, dose variations, substrate orientation variation or screen oxide layer thickness variation on the wafer surface. Therefore, as the thickness of the implantation oxide layer is increased, the current gain factor of the semiconductor device 1 decreases and in fact the current gain can vary widely as a function of the implantation oxide thickness. The problem of a varying implant dopant profile already occurs at dopant implantation energies of 40 keV and less, with a corresponding range of implant screen oxide thicknesses.

### SUMMARY

The invention provides a method of manufacturing a semiconductor device. The method comprises growing an implantation oxide layer, implanting a dopant and activating the dopant. Further, the method comprises removing the implantation oxide layer after the step of activating the dopant. An implantation oxide layer (implantation screen oxide) is grown or deposited, for example, on the wafer surface, where the wafer can be silicon, for example. A dopant is then implanted into the device, where it diffuses during the dopant activation cycle through the implantation oxide layer and into the active region below. After the dopant has been activated, the implantation oxide layer is removed. The implantation oxide layer is thus used as an additional dopant source during the diffusion process and activation of the dopant. There is then no need to rely purely on the dopant concentration in the wafer. After the dopant has been activated, the implant oxide layer is removed. In this way, the sensitivity of the doping profile to implantation oxide layer thickness variations is reduced. Furthermore, the dopant profile is improved compared to that resulting from known processes, since it provides a locally reduced concentration in the base region, in the case where the semiconductor device is an NPN transistor. In other words, the width of the gap between the bottom of the base well and the lower boundary of the active region of the device is reduced. Variation of the dopant sheet resistance and surface concentration is then linear as a function of implantation oxide layer thickness. This means that the resultant device will have a higher gain than devices manufactured according to prior art methods and also a reduced dependency of the gain on the thickness of the implantation oxide layer thickness. The invention provides a method of manufacturing an NPN transistor in BiCMOS technology with a very high current gain in regions from 700-10000. This includes the use of the standard emitter profile (e.g. as shown in FIG. 3, Layer 17a, plus an emitter extension Layer 17b).

In one embodiment of the invention, the step of implanting the dopant can take place at an energy at or below 40 keV. In conventional processes, using an implant energy of 40 keV and below leads to a variation in the dopant profile. However, with the method of the invention, implant energies of 40 keV and below may be used since removing the screen oxide takes place after activation of the dopant.

The dopant used to establish a dopant profile in the device may be arsenic, for example. Advantageously, the method according to the invention provides that the sensitivity of the arsenic profile to variations in the thickness of the implantation oxide layer (screen oxide layer) can be reduced.

Advantageously, the step of activating the dopant is performed by an annealing process. This heats the dopant ions or atoms and causes them to diffuse into the device, for example into the base region in the case where the device is bipolar junction transistor. The process of annealing to activate the dopant can be performed by heating the device to a temperature of, for example, from 900° C. to 1050° C.

In a particularly advantageous embodiment, the implantation oxide layer may be grown to a thickness of 85×10⁻¹⁰ m (85 \acute{Å}) or greater. In conventional processes for manufacturing semiconductor devices, when the implantation oxide layer has a thickness greater than 85×10⁻¹⁰ m, the dopant surface concentration decreases and the dopant sheet resistance increases by such an amount that the gain of the device is reduced. However, for a device manufactured according to the method of the invention, it is possible to have an implantation oxide layer with a thickness of 85×10⁻¹⁰ m (85 \acute{Å}) without affecting the gain of the device, since the dopant surface concentration and the dopant sheet resistance show a greatly reduced dependency on the thickness of the implantation oxide layer.

The semiconductor device manufactured according to the method of the invention may advantageously be an NPN bipolar transistor. NPN transistors in BICMOS technology are especially advantageously manufactured by the method according to the invention, since the dopant surface concentration and the dopant sheet resistance have a greatly reduced sensitivity to the thickness of the implantation oxide layer. This means that the gain of the NPN transistor is not dependent on the implantation oxide thickness and current gains with good control of, for example, a target value of 1500 may be achieved.

### BRIEF DESCRIPTION OF THE DRAWINGS

Further advantages and characteristics of the invention ensue from the description below of a preferred embodiment, and from the accompanying drawings, in which:

FIG. 1 is a simplified schematic of part of a semiconductor device manufactured by a known method;

FIG. 2 is a simplified schematic of a stage of manufacture of a semiconductor device manufactured using a method according to an exemplary embodiment of the invention;

FIG. 3 is a simplified schematic of part of a semiconductor device manufactured by a method according to an exemplary embodiment of the invention;

FIG. 4 is a graph of dopant concentration as a function of thickness of an implant screen oxide layer in a semiconductor device manufactured according to a prior art method and a semiconductor device manufactured by a method according to an exemplary embodiment of the invention; and

FIG. 5 is a graph of dopant concentration as a function of thickness of an implant screen oxide layer in a semiconductor device manufactured according to a prior art method and a semiconductor device manufactured by a method according to an exemplary embodiment of the invention.

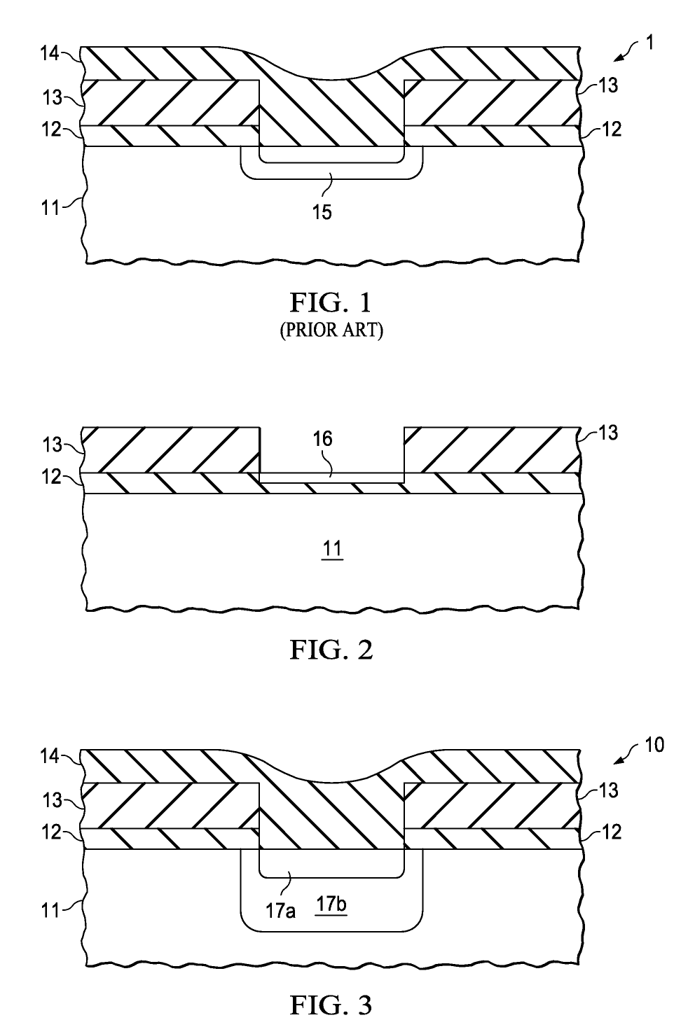

### DETAILED DESCRIPTION OF AN EXAMPLE EMBODIMENT

FIGS. 2 and 3 show two different stages of manufacturing a part of a semiconductor device 10 according to one embodiment of the invention. Just as an example, manufacturing stages of a part of an NPN transistor are shown, in particular the active region including the base electrode structure.

A silicon layer 11 for forming the active base region of the semiconductor device 10 has an oxide layer 12 deposited on its surface. A nitride layer 13, for example a silicon nitride (Si₃Ni₄) layer is then deposited on top of the oxide layer 12. The silicon nitride layer 13 is then masked, apart from an area where a dopant is to be implanted for forming the base region. This area of the nitride layer 13 is etched all the way through, with the etch stopping in the oxide layer 12. In other words, the oxide layer 12 is partially etched. A screen or implantation oxide layer 16 (implant screen oxide layer) is then deposited on top of the surface of the etched-back part of the oxide layer 12. The implantation oxide layer 16 may generally be grown or deposited to a thickness of between 60 and 110 \acute{Å} (60-110×10⁻¹⁰ m), for example, and most preferably to a thickness of greater than 85×10⁻¹⁰ m.

Then the Implantation of the dopant may be carried out, for example, by using an ion implantation process. The dopant is then activated by annealing the device 10 to a temperature; for example, from 900° C. up to 1050° C. (up to 1100° C. is also possible). This causes dopant atoms to diffuse from the implantation oxide layer 16 and the silicon layer 11 to establish a dopant profile (17b shown in FIG. 3) in the layer 11, which forms the base region of the device 10. The screen oxide layer 16 is then removed.

FIG. 3 shows the next step of manufacture of the semiconductor device 10. A polysilicon layer 14 is deposited on the top of the device so that it covers the surface of the silicon nitride layer 13 and the surface of the screen

The emitter dopant profile 17a is shallow. The emitter extension 17b is compensating the dopant concentration of the base silicon layer 11 effectively reducing the final base width of the silicon layer 11 forming the active region of the device 10.

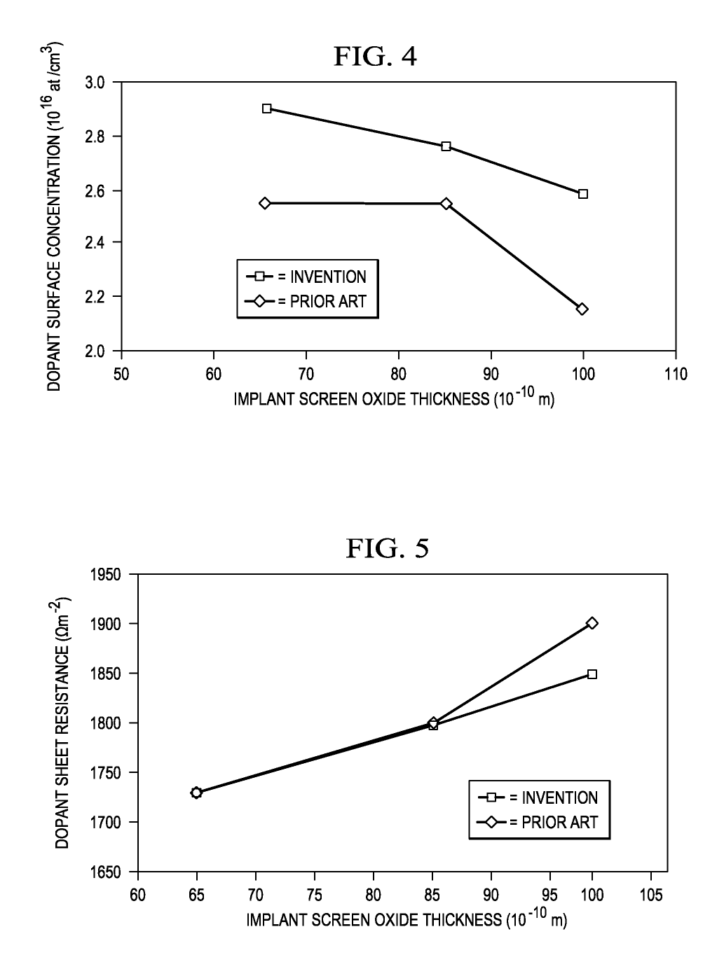

FIG. 4 shows a graph of the dopant surface concentration as a function of thickness of the screen oxide layer 16 for a semiconductor device manufactured according to the prior art method and for a semiconductor device manufactured according to the method of the invention. In the device manufactured according to the prior art method, up to a thickness of 85×10⁻¹⁰ m the dopant surface concentration for the prior art process is constant and then, when the thickness of the implant screen oxide layer 16 increases beyond 85×10⁻¹⁰ m, the dopant surface concentration decreases with a steep gradient as a function of the implant oxide layer thickness. In other words, the dopant surface concentration does not vary linearly with the implant oxide layer thickness and is very sensitive to variations in implant oxide layer thickness for thicknesses above 85×10⁻¹⁰ m. For the device manufactured according to the method of the invention described above, the dopant surface concentration decreases linearly as a function of implant oxide layer thickness, even above thicknesses of 85×10⁻¹⁰ m. However, the gradient of decrease is not as steep as that for the device manufactured according to the prior art process. As the implant oxide layer thickness is increased from 85×10⁻¹⁰ m to 100×10⁻¹⁰ m, the dopant surface concentration in the device manufactured according to the invention decreases by less than 0.2×10¹⁶ atoms/cm³. This is compared to a decrease of around 0.4×10¹⁶ atoms/cm³ in the device manufactured according to the prior art process.

FIG. 5 shows a graph of the dopant sheet resistance as a function of the implantation (screen) oxide layer thickness. Up to a thickness of 85×10⁻¹⁰ m, the dopant sheet resistance for the prior art process increases linearly and then, when the thickness of the screen oxide layer 16 increases beyond 85×10⁻¹⁰ m, the dopant surface concentration increases more steeply. However, for the device manufactured according to the invention, the increase in the dopant sheet resistance is linear, even above an implantation oxide layer thickness of 85×10⁻¹⁰ m. Furthermore, the increase in dopant sheet resistance for a device manufactured according to the invention when the thickness of the implantation oxide layer is increased from 85×10⁻¹⁰ m to 100×10⁻¹⁰ m is less than half the increase in dopant sheet resistance for a device manufactured according to the prior art method. This means that when an NPN transistor is manufactured according to the method of the invention, the gain of the transistor is much less sensitive to implantation oxide layer thickness, even when the thickness is greater than 85×10⁻¹⁰ m, and current gains of up to 1500 may be achieved.

Although the invention has been described hereinabove with reference to a specific embodiment, it is not limited to this embodiment and no doubt further alternatives will occur to the skilled person that lie within the scope of the invention as claimed.

What is claimed is:

1. A method of manufacturing a semiconductor device, the method comprising:
forming an implantation oxide layer;
implanting a dopant;
activating the dopant; and
removing the implantation oxide layer after the step of activating the dopant.

2. The method according to claim 1, wherein the step of implanting the dopant takes place at an energy at or below 40 keV.

3. The method according to claim 1, wherein the dopant is arsenic.

4. The method according to claim 1, wherein the step of activating the dopant is performed by an annealing process.

5. The method according to claim 4, wherein the annealing process is performed at a temperature of from 900° C. to 1050° C.

6. The method according claim 1, wherein the step of forming the implantation oxide layer comprises growing the implantation oxide layer to a thickness of greater than 85×10⁻¹⁰ m.

7. A semiconductor device manufactured according to claim 1.

8. An NPN bipolar transistor being manufactured according to the method of claim 1.
